(19) United States
(12) Patent Application Publication
(10) Pub. No.: US 2022/0091332 A1
(43) Pub. Date: Mar. 24, 2022

(54) ELECTRONIC-PHOTONIC INTEGRATED CIRCUIT BASED ON SILICON PHOTONICS TECHNOLOGY

(71) Applicant: ELECTRONICS AND TELECOMMUNICATIONS RESEARCH INSTITUTE, Daejeon (KR)

(72) Inventors: Sanghwa YOO, Daejeon (KR); Heuk PARK, Daejeon (KR); Jyung Chan LEE, Daejeon (KR); Joon Ki LEE, Sejong-si (KR)

(21) Appl. No.: 17/371,520

(22) Filed: Jul. 9, 2021

(30) Foreign Application Priority Data
Sep. 18, 2020 (KR) 10-2020-0120599
Apr. 1, 2021 (KR) 10-2021-0042655

(51) Int. Cl. G02B 6/12; G02B 6/42; G02B 6/43

(52) U.S. Cl. CPC G02B 6/12004; G02B 6/12002; G02B 2006/12142; G02B 6/43; G02B 2006/12061; G02B 6/428

(57) ABSTRACT

Disclosed is a silicon photonics-based electronic-photonic integrated circuit (EPIC). The silicon photonics-based EPIC includes a silicon photonic integrated circuit (PIC) chip in which an optical device is mounted on a silicon-on-insulator (SOI) wafer including a trench region, an electronic integrated circuit (EIC) chip mounted in the trench region of the PIC chip, and an electrical interface configured to connect an electrode pad of the PIC chip and an electrode pad of the EIC chip.

### CROSS-REFERENCE TO RELATED APPLICATION(S)

This application claims the priority benefit of Korean Patent Application No. 10-2020-0120599 filed on Sep. 18, 2020, and Korean Patent Application No. 10-2021-0042655 filed on Apr. 1, 2021, in the Korean Intellectual Property Office, the disclosures of which are incorporated herein by reference for all purposes.

### BACKGROUND

### 1. Field of the Invention

One or more example embodiments relate to a silicon photonics-based electronic-photonic integrated circuit (EPIC), and more particularly, to a structure of the silicon photonics-based EPIC that may effectively release generated heat while minimizing a loss of a high-speed electrical signal.

### 2. Description of Related Art

Silicon photonics may be a solution for a low optical propagation loss, a low power consumption, and a high bandwidth, and to intra- and/or inter-data center traffic and telecom traffic that is exponentially increasing by advanced complementary metal-oxide semiconductor (CMOS)-compatible process.

A silicon photonic integrated circuit (PIC), which is manufactured by integrating various optical devices onto a single chip, may greatly reduce the packaging costs and size. The optical devices may include active devices, such as, for example, an optical modulator having an electro-optical (EO) conversion function and a photodetector (PD) having an opto-electrical (OE) conversion function, and passive devices, such as, for example, an optical multiplexer/inverse multiplexer, an optical coupler, and a polarization controlling device.

The silicon PIC may be monolithically integrated as a single chip with an electronic integrated circuit (EIC). The EIC may include a driver for driving an optical modulator and a transimpedance amplifier (TIA) for amplifying an electrical signal output from a PD. However, the EIC may be manufactured by the most highly advanced CMOS process with a pattern of 28 nanometers (nm) or less, whereas the PIC may be manufactured with a relatively greater size of patterns than the EIC, for example, a minimum pattern of approximately 100 nm or less. For this reason, an electronic-photonic integrated circuit (EPIC) in which the PIC and the EIC are combined through hybrid integration has recently been employed more in the related industries due to its cost-effectiveness.

Thus, a typical three-dimensional (3D) integration structure in which an EIC chip (or an application-specific integrated circuit (ASIC)) is flip-chip bonded to a silicon PIC chip may flip-chip bond the EIC (or ASIC) chip and the PIC chip through a solder bump without a long bonding wire and allow a high-speed electrical signal to propagate an extremely short distance, thereby reducing a loss of the high-speed electrical signal.

However, for a silicon PIC of such a typical structure, a silicon-on-insulator (SOI) wafer or a bulk silicon wafer may be used to form a silicon waveguide. In particular, when using the SOI wafer or the bulk silicon wafer, a buried oxide (BOX) region may be required to be formed. In such a case, the heat generated in the EIC (or ASIC) chip may not be released outside when it is transferred to the PIC due to a several micrometers (μm)-thick BOX layer.

In addition, a typical two-dimensional (2D) integration structure in which a laser diode (LD) chip corresponding to the PIC and an LD driver chip corresponding to the EIC are bonded onto a circuit board and connected by a bonding wire may reduce or minimize a stepped portion between an electronic pad of the LD chip and an electronic pad of the driver chip using a sub-mount disposed between the LD chip and the circuit board. The circuit board and the sub-mount may be thermally connected to each other, and the circuit board may include an insulator and have a function of a heat sink that releases the heat generated in the LD chip and the driver chip.

Thus, a silicon PIC of such a typical structure may easily release the heat generated in the EIC and the PIC. However, the silicon PIC of this structure may lose a high-speed electrical signal due to a relatively long bonding wire, and become more complex due to the addition of a cover layer and a sub-mount layer onto a base layer, increasing the number of structures to be stacked.

### SUMMARY

An aspect provides an electronic-photonic integrated circuit (EPIC) structure that is provided by disposing an electronic integrated circuit (EIC) chip on a photonic integrated circuit (PIC) chip including a trench region and may thus release heat that is generated in the EIC chip through a silicon substrate with high thermal conductivity of the PIC chip. The EPIC structure may thus effectively release heat without an additional functional block.

Another aspect also provides a method of minimizing a length of an electrical interface that connects two electrode pads—an electrode pad of the PIC chip and an electrode pad of the EIC chip—which are provided to have the same height by adjusting a process depth of a trench region.

Still another aspect provides a method of improving chip alignment accuracy and reducing an alignment load using a remaining region in which a trench region is not formed as a guide rail for mounting an EIC chip.

According to an aspect, there is provided a silicon photonics-based electronic-photonic integrated circuit (EPIC), the EPIC including a silicon photonic integrated circuit (PIC) chip in which an optical device is mounted on a silicon-on-insulator (SOI) wafer including a trench region, an electronic integrated circuit (EIC) chip mounted in the trench region of the PIC chip, and an electrical interface configured to connect an electrode pad of the PIC chip and an electrode pad of the EIC chip.

The EIC chip may be mounted on a silicon substrate of the SOI wafer in the trench region from which cladding oxide, silicon, and buried oxide (BOX) of the SOI wafer are removed.

The EIC chip may be fixed to a silicon substrate of the SOI wafer using a thermally conductive adhesive.

A depth of the trench region may be determined such that the electrode pad of the PIC chip and the electrode pad of the EIC chip have a same height.

The electrode pad of the PIC chip and the electrode pad of the EIC chip are designed to have a same pitch spacing.

According to another aspect, there is provided a silicon photonics-based EPIC, the EPIC including a silicon PIC chip in which an optical device is mounted on a SOI wafer including a first trench region and a second trench region, an EIC chip mounted in the first trench region of the PIC chip, an electrical interface configured to connect an electrode pad of the PIC chip and an electrode pad of the EIC chip, and an N-channel fiber array block (FAB) having one or more channels mounted in the second trench region of the PIC chip.

The EIC chip may be mounted on a silicon substrate of the SOI wafer in the first trench region from which cladding oxide, silicon, and BOX of the SOI wafer are removed.

The N-channel FAB may be mounted on a silicon substrate of the SOI wafer in the second trench region from which cladding oxide, silicon, and BOX of the SOI wafer are removed.

The EIC chip may be fixed to a silicon substrate of the SOI wafer using a thermally conductive adhesive.

The N-channel FAB may be fixed to a silicon substrate of the SOI wafer using an adhesive.

A depth of the first trench region may be determined such that the electrode pad of the PIC chip and the electrode pad of the EIC chip have a same height.

The electrode pad of the PIC chip and the electrode pad of the EIC chip may be designed to have a same pitch spacing.

According to still another aspect, there is provided a silicon photonics-based EPIC, the EPIC including a silicon PIC chip in which an optical device is mounted on a SOI wafer including a trench region, an EIC chip mounted in the trench region of the PIC chip, an electrical interface configured to connect an electrode pad of the PIC chip and an electrode pad of the EIC chip, and a printed circuit board (PCB) including a thermally conductive via disposed at a bottom of the PIC chip.

The PCB may be fixed to an upper PCB on which an electrode pad is mounted using an adhesive.

A height of the upper PCB may be determined such that the electrode pad of the upper PCB and the electrode pad of the EIC chip have a same height.

The EIC chip may be mounted on a silicon substrate of the SOI wafer in the trench region from which cladding oxide, silicon, and BOX of the SOI wafer are removed.

A depth of the trench region may be determined such that the electrode pad of the PIC chip and the electrode pad of the EIC chip have a same height.

According to yet another aspect, there is provided a silicon photonics-based EPIC, the EPIC including a silicon PIC chip in which an optical device is mounted on a SOI wafer including a trench region, an EIC chip mounted in the trench region of the PIC chip, and an interposer configured to connect an electrode pad of the PIC chip and an electrode pad of the EIC chip through a solder bump.

The EIC chip may be mounted on a silicon substrate of the SOI wafer in the trench region from which cladding oxide, silicon, and BOX of the SOI wafer are removed.

A depth of the trench region may be determined such that the electrode pad of the PIC chip and the electrode pad of the EIC chip have a same height.

The electrode pad of the PIC chip and the electrode pad of the EIC chip may be connected through an electrical interface in the interposer.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIGS. 1A through 1D are diagrams illustrating an example of a structure of a silicon photonics-based electronic-photonic integrated circuit (EPIC) according to an example embodiment;

FIGS. 2A through 2C are diagrams illustrating an example of a structure of a silicon photonics-based EPIC according to another example embodiment;

FIG. 3 is a diagram illustrating an example of a structure of a silicon photonics-based EPIC according to another example embodiment;

FIG. 4 is a diagram illustrating an example of a structure of a silicon photonics-based EPIC according to another example embodiment;

FIGS. 5A and 5B are diagrams illustrating an example of a structure of a silicon photonics-based EPIC according to another example embodiment;

FIGS. 6A and 6B are diagrams illustrating an example of a structure of a silicon photonics-based EPIC according to another example embodiment;

FIGS. 7A and 7B are diagrams illustrating an example of a structure of a silicon photonics-based EPIC according to another example embodiment; and

FIG. 8 is a diagram illustrating an example of a structure of a silicon photonics-based EPIC according to another example embodiment.

### DETAILED DESCRIPTION

Hereinafter, example embodiments will be described in detail with reference to the accompanying drawings.

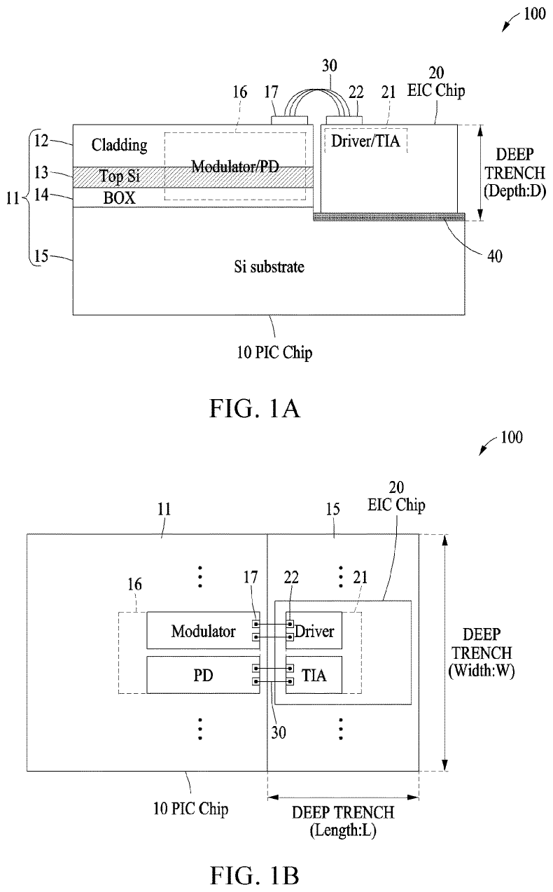

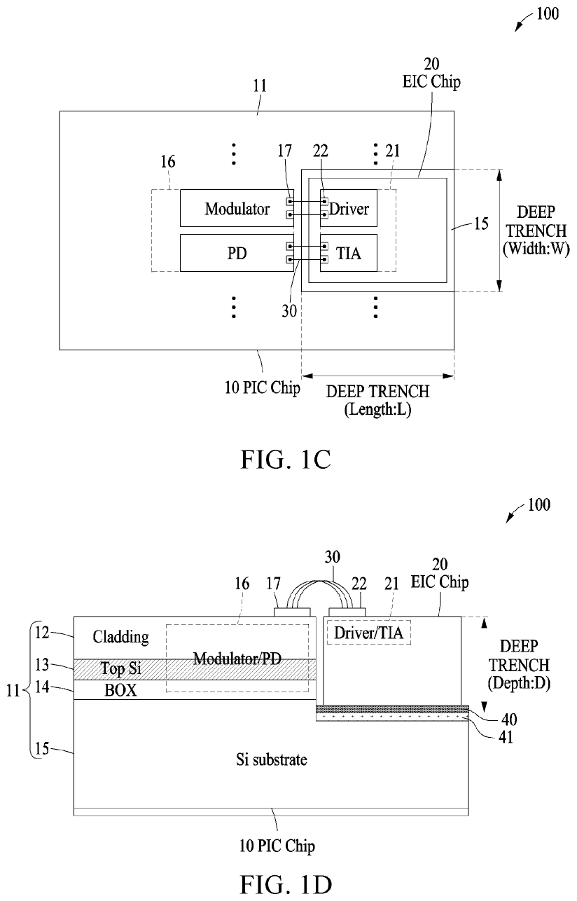

FIGS. 1A through 1D are diagrams illustrating an example of a structure of a silicon photonics-based electronic-photonic integrated circuit (EPIC) according to an example embodiment.

FIG. 1A illustrates a side view of a silicon photonics-based EPIC 100. The silicon photonics-based EPIC 100 may include a silicon photonic integrated circuit (PIC) chip 10 provided in a silicon-on-insulator (SOI) wafer 11 including a trench region (or a deep trench as illustrated), an electronic integrated circuit (EIC) chip 20 formed in the trench region of the PIC chip 10, and an electrical interface 30 connecting an electrode pad 17 of the PIC chip 10 and an electrode pad 22 of the EIC chip 20.

FIGS. 1B and 1C illustrate top views of the silicon photonics-based EPIC 100. FIG. 1B is the top view of the EPIC 100 in which a width of the trench region of the PIC chip 10 is formed to be the same as the overall width of the PIC chip 10. FIG. 1C is the top view of the EPIC 100 in which the width of the trench region of the PIC chip 10 is formed such that a margin is added to a width of the EIC chip 20. A remaining region in which the trench region is not formed as illustrated in FIG. 1C may function as a guide rail when the EIC chip 20 is mounted and may thus improve chip alignment accuracy.

Specialized EIC chips, for example, the EIC chip 20, may need their bottom surfaces to be electrically connected with the ground. The silicon photonics-based EPIC 100 may include a separate metal layer 41 in the trench region, and a thermally conductive adhesive 40 used to fix the EIC chip 20 into the trench region may also be electrically conductive.

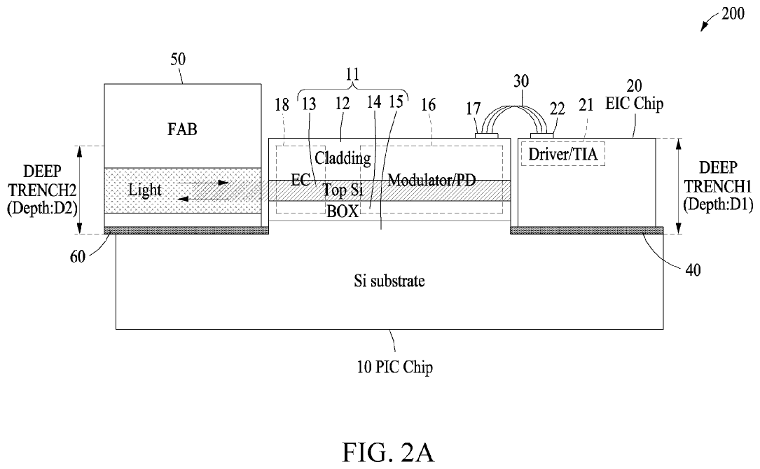

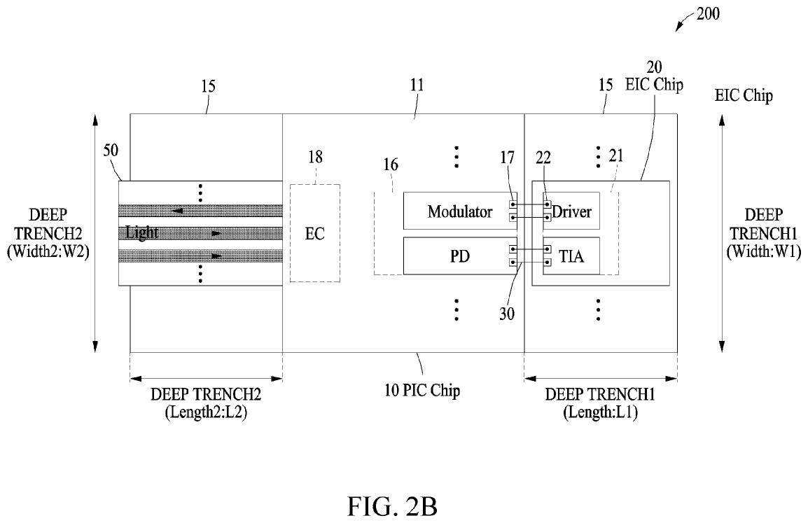

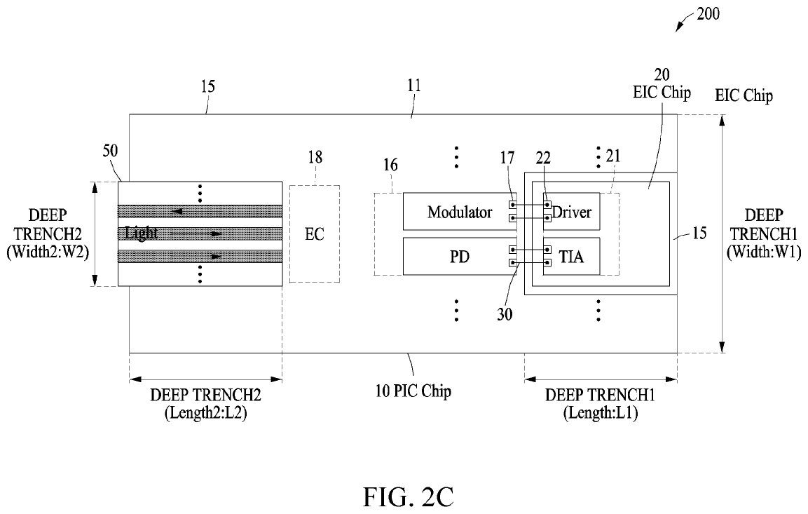

A detailed structure of the silicon photonics-based EPIC 100 will be described hereinafter with reference to FIGS. 2A through 2C.

FIGS. 2A through 2C are diagrams illustrating an example of a structure of a silicon photonics-based EPIC according to another example embodiment.

FIG. 2A illustrates a side view of a silicon photonics-based EPIC 200. The silicon photonics-based EPIC 200 may include a silicon PIC chip 10 provided in an SOI wafer 11 including a first trench region and a second trench region, an EIC chip 20 disposed in the first trench region (or deep trench 1 as illustrated), an electrical interface 30 connecting an electrode pad 17 of the PIC chip 10 and an electrode pad 22 of the EIC chip 20, and an N-channel fiber array block (FAB) 50 disposed in the second trench region (or deep trench 2 as illustrated). Here, N may be greater than or equal to 1 (N1).

FIGS. 2B and 2C illustrate top views of the silicon photonics-based EPIC 200. FIG. 2B is the top view of the EPIC 200 in which a width of a first trench region of the PIC chip 10 and a width of a second trench region of the PIC chip 10 are formed to be the same as the overall width of the PIC chip 10. FIG. 2C is the top view of the EPIC 200 in which the width of the first trench region of the PIC chip 10 and the width of the second trench region of the PIC chip 10 are formed such that a margin is added to the width of the EIC chip 20 and the width of the FAB 50, respectively. A remaining region in which the trench regions are not formed as illustrated in FIG. 2C may function as a guide rail when the EIC chip 20 and the FAB 50 are mounted, and thus improve chip alignment accuracy.

An optical device of the PIC chip 10 may be provided or implemented on the SOI wafer 11 on which an oxide film is deposited. The SOI wafer 11 of a general type may be stacked with a silicon substrate 15 with a thickness of 725 micrometers (μm) or less, buried oxide (BOX) 14 with a thickness of 2-3 and silicon 13 with a thickness of 200-400 nm, and include cladding oxide 12 and a metal electrode 17 that are formed through a back-end-of-line (BEOL) process.

In the silicon PIC chip 10 provided on the SOI wafer 11 including the first trench region and the second trench region, a depth D of the first trench region may need to suffice the removal of the BOX 14. That is, only the silicon substrate 15 may remain in the first trench region with the cladding oxide 12, the silicon 13, and the BOX 14 removed.

A desirable depth of the first trench region may be determined based on a height of the electrode pad 22 of the EIC chip 20 and a thickness of a thermally conductive adhesive 40 disposed between the EIC chip 20 and the PIC chip 10.

In order to transmit a high-speed electrical signal, a length of an electrical interface 30 may need to be sufficiently short, and thus the PIC chip 10 and the EIC chip 20 may need to be arranged at positions closest to each other. For the electrical interface 30, a maximum length of 180 μm is required in related industries when a bonding wire is used as the electrical interface 30. However, as the length decreases, a transmission performance of a high-speed electrical signal may be improved.

In general, the PIC chip 10 is thicker than the EIC chip 20. According to an example embodiment, the length of the electrical interface 30 may be provided as a shortest distance by adjusting the depth of the first trench region and matching the heights of the electrode pad 17 of the PIC chip 10 and the electrode pad 22 of the EIC chip 20. Thus, a loss of the high-speed electrical signal by a frequency that is induced by an inductive component in the electrical interface 30 may be minimized. The depth of the first trench region described above may be provided merely as an example. The depth of the first trench region may be determined such that the height of the electrode pad 17 of the PIC chip 10 and the height of the electrode pad 22 of the EIC chip 20 are different from each other.

According to example embodiments, it is possible to improve practicality by utilizing infrastructure of an existing bonding wire-based interconnection technology and minimizing a high-speed signal loss. However, when the length is extremely short, a solder bump may be formed in each electrode pad, and the electrode pads may be connected through soldering.

According to example embodiments, it is possible to achieve a highly dense high-speed electrical signal interface by designing to match a pitch spacing between electrode pads 17 of the PIC chip 10 and a pitch spacing between electrode pads 22 of the EIC chip 20 or designing the pitch spacing between the electrode pads 17 of the PIC chip 10 and the pitch spacing between the electrode pads 22 of the EIC chip 20 to be as similar as possible in a preset error range.

A trench region may be approximately 100 μm, which corresponds to the thickness of the EIC chip 20, based on a radius (125 μm/2 or less) of a single-mode optical fiber (SMF). For the EIC chip 20 with a thickness of more than 100 μm, the depth of the trench region may be adjusted to increase to be matched to a similar level to the thickness.

A process for a trench region may be a silicon photonics process that is required to allow the SMF to access an edge coupler (EC) 18 which is an optical input/output device of the PIC chip 10. In addition, the silicon PIC chip 10 provided on the SOI wafer 11 including the trench region uses the existing process, and thus manufacturing an additional mask layer may not be needed and the complexity of the process may not be increased.

A mask layout of a trench region may need to be designed with a minimum pattern length (L, W) based on an allowable aspect ratio (AR). In general, a mask layout of a trench region with a 100 μm depth D may need to be designed with a 100 μum pattern length (AR≈1).

A connection surface between the EIC chip 20 and the PIC chip 10 that is formed in the first trench region may be bonded using a thermal epoxy which is the thermally conductive adhesive 40. The thermally conductive adhesive 40 may be used after a medium with high thermal conductivity such as copper is applied on the silicon substrate 15 of the PIC chip in an additional BEOL process. A connection surface between the FAB 50 and the PIC chip 10 that is formed in the second trench region may be fixed using an adhesive 60, and the thermally conductive adhesive 40 may be used for simplifying the manufacture of an optical module.

In the silicon photonics-based EPIC 100 or 200, the EIC chip 20 may be connected to the silicon substrate 15 of the PIC chip 10, and thus the heat generated in the EIC chip 20 may be released outside through the silicon substrate 15 with great heat transfer properties. The silicon substrate 15 may be known to have a heat transfer coefficient that is approximately 100 times higher than that of the cladding oxide 12 or the BOX 14 (Si: 148W/m·K, SiO2: 1.4W/m·K).

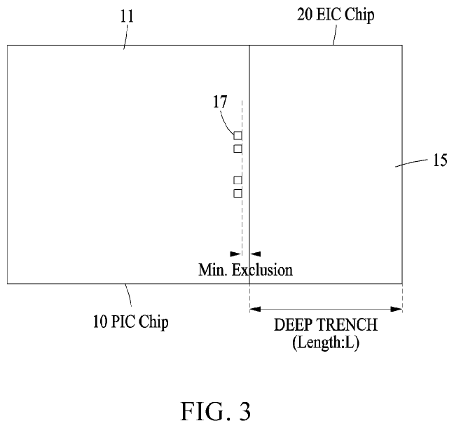

Based on an existing silicon photonics dicing process, the electrode pad 17 of the PIC chip 10 may need to be designed with an approximately 50 μm margin from an edge of the chip because a side of the chip may be irregularly abraded due to the dicing process. As illustrated in FIG. 3, a process for a trench region may cleanly cut an etching side of the PIC chip 10, and thus significantly reduce the 50 μm margin to a minimum exclusion value (or min. exclusion as illustrated) specified as per a design rule on a semiconductor process, thereby minimizing the length of the electrical interface 30. In general, the minimum exclusion may be approximately 1

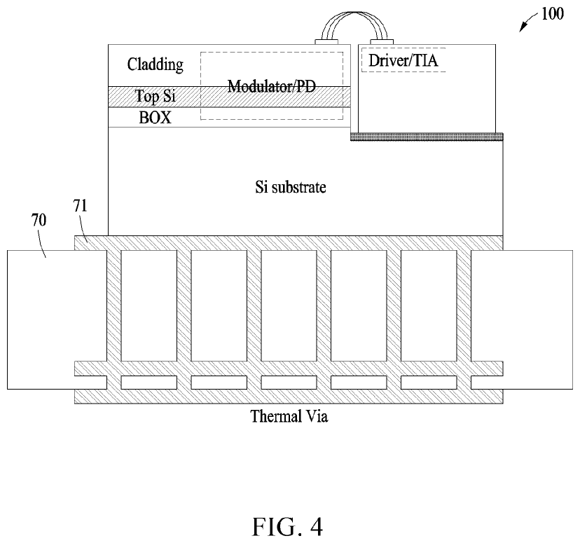

FIG. 4 is a diagram illustrating an example of a structure of a silicon photonics-based EPIC according to another example embodiment.

Referring to FIG. 4, the silicon photonics-based EPIC 100 may be disposed on a general PCB-based substrate 70 including a thermal via 71. The PCB-based substrate 70 may function as a heat sink by releasing heat emitted from the silicon photonics-based EPIC 100 outside through the thermal via 71.

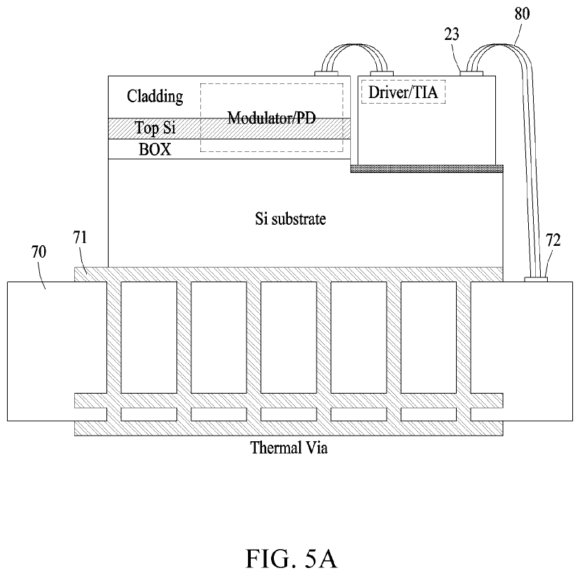

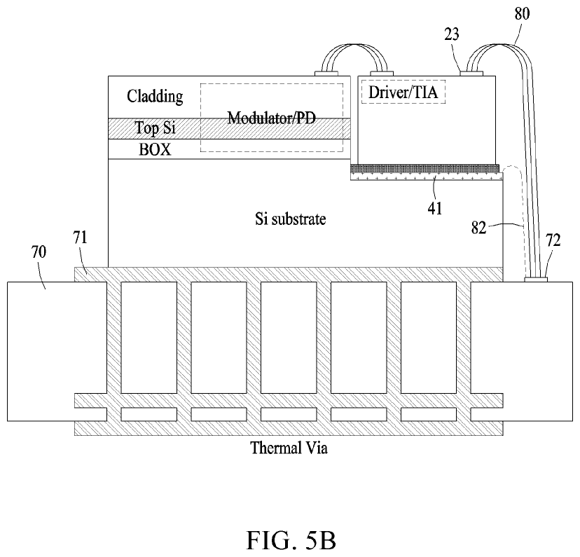

FIGS. 5A and 5B are diagrams illustrating an example of a structure of a silicon photonics-based EPIC according to another example embodiment.

Referring to FIG. 5A, an electrode pad 23 of the silicon photonics-based EPIC 100 may be connected to an electrode pad 72 of a PCB-based substrate 70 through an electrical interface 80, and a high-speed electrical signal may be input and output through the electrical interface 80.

Referring to FIG. 5B, the silicon photonics-based EPIC 100 may include a separate metal layer 41 in a trench region. The metal layer 41 included in the trench region may be connected to the electrode pad 72 of the PCB-based substrate 70 through an electrical interface 82. Although the electrode pad 72 is illustrated as one electrode pad for convenience, it may include a signal electrode pad and a ground electrode pad.

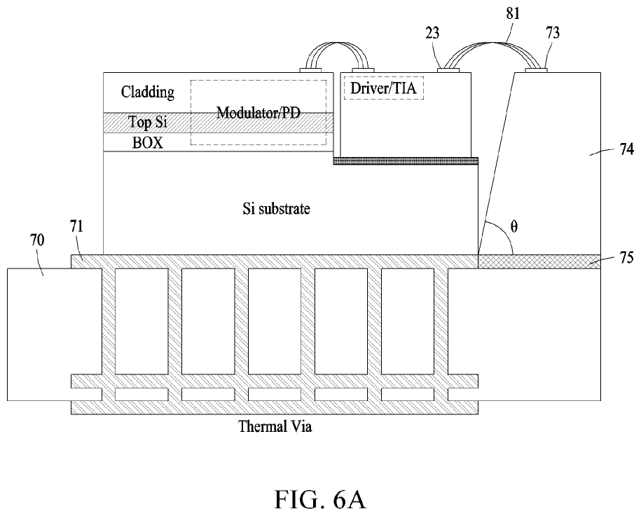

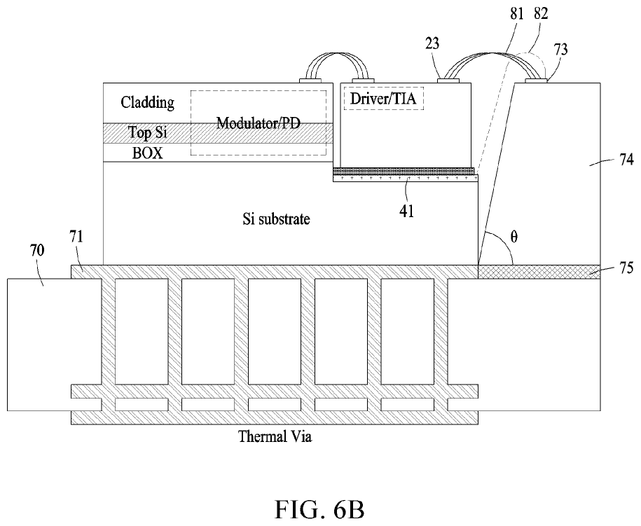

FIGS. 6A and 6B are diagrams illustrating an example of a structure of a silicon photonics-based EPIC according to another example embodiment.

Referring to FIG. 6A, the electrode pad 23 of the silicon photonics-based EPIC 100 may be connected, through an electrical interface 81, to an electrode pad 73 of an upper PCB-based substrate 74 stacked on a PCB-based substrate 70. A high-speed electrical signal may be input and output through the electrical interface 81.

A length of the electrical interface 81 may be shorter than the length of the electrical interface 80 illustrated in FIG. 5A or 5B, and thus be more effective in the transmission of a high-speed electrical signal. In such a stacked PCB structure, a minimum length of the electrical interface 81 may be determined based on a side angle θ of an upper PCB-based substrate 74 and the degree of an adhesive leakage between the two PCB-based substrates 70 and 74.

Referring to FIG. 6B, the silicon photonics-based EPIC 100 may include a separate metal layer 41 in a trench region. The metal layer 41 included in the trench region may be connected to the electrode pad 73 of the PCB-based substrate 74 through an electrical interface 82. Although the electrode pad 73 is illustrated as one electrode pad for convenience, it may include a signal electrode pad and a ground electrode pad.

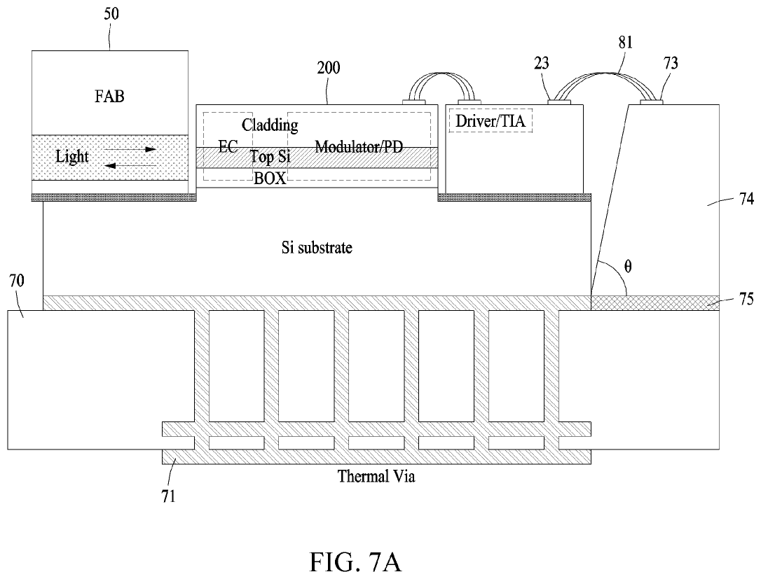

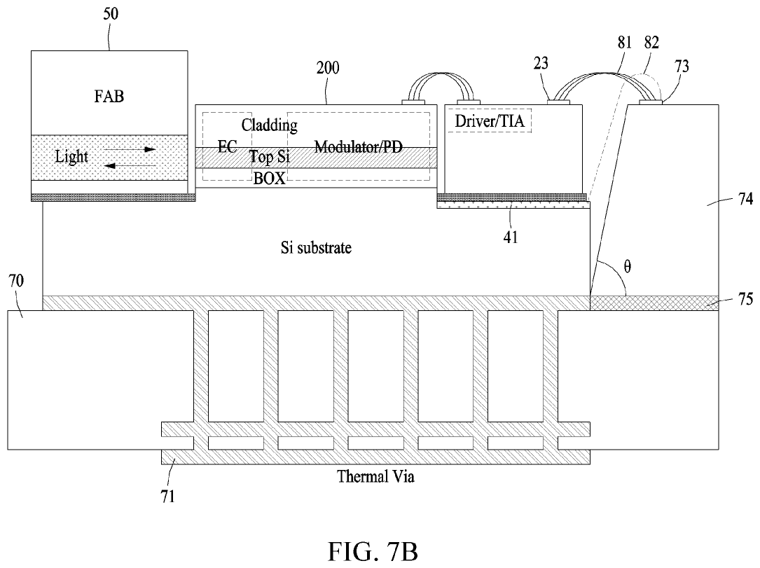

FIGS. 7A and 7B are diagrams illustrating an example of a structure of a silicon photonics-based EPIC according to another example embodiment.

Referring to FIG. 7A, an electrode pad 23 of the silicon photonics-based EPIC 200 in which the FAB 50 is provided and an electrode pad 73 of the upper PCB-based substrate 74 stacked on the PCB-based substrate 70 may be connected through the electrical interface 81.

Referring to FIG. 7B, the silicon photonics-based EPIC 200 may include a separate metal layer 41 in a trench region. The metal layer 41 included in the trench region may be connected to the electrode pad 73 of the upper PCB-based substrate 74 through an electrical interface 82.

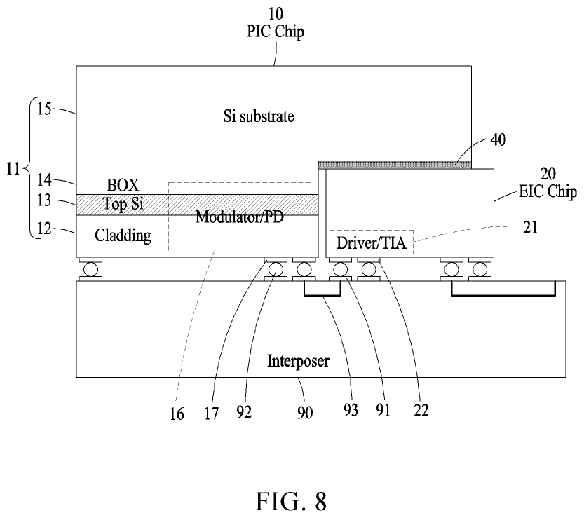

FIG. 8 is a diagram illustrating an example of a structure of a silicon photonics-based EPIC according to another example embodiment.

Referring to FIG. 8, the silicon photonics-based EPIC 100 may be flip-chip bonded with a thermally conductive interposer 90. The electrode pad 17 of the PIC chip 10 may be flip-chip bonded to an electrode pad 91 of the interposer 90 through a solder bump 92, and the electrode pad 22 of the EIC chip 20 may be flip-chip bonded to the electrode pad 91 of the interposer 90 through the solder bump 92.

The silicon photonics-based EPIC 100 may be effective because it may release heat generated from the EIC chip 20 in two directions: upward and downward. In addition, an electrical interface 93 between the PIC chip 10 and the EIC chip 20 may be provided to have a shortest distance, reducing a loss of a high-speed electrical signal.

According to example embodiments, an EPIC structure in which an EIC chip is disposed on a PIC chip including a trench region may release heat generated in the EIC chip through a silicon substrate with high thermal conductivity of the PIC chip, and thus effectively release heat without an additional functional block.

According to example embodiments, it is also possible to minimize a length of an electrical interface connecting two electrode pads (an electrode pad of a PIC chip and an electrode pad of an EIC chip) by adjusting a process depth of a trench region such that the electrode pads have the same height.

According to example embodiments, it is possible to improve chip alignment accuracy and reduce an alignment load by using, as a guide rail, a remaining region in which a trench region is not formed when mounting an EIC chip.

The components described in the example embodiments may be implemented by hardware components including, for example, at least one digital signal processor (DSP), a processor, a controller, an application-specific integrated circuit (ASIC), a programmable logic element, such as a field programmable gate array (FPGA), other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

In the meantime, the method according to an example embodiment may be implemented as various recording media such as a magnetic storage medium, an optical read medium, and a digital storage medium after being implemented as a program that can be executed in a computer.

The implementations of the various technologies described in the specification may be implemented with a digital electronic circuit, computer hardware, firmware, software, or the combinations thereof. The implementations may be achieved as a computer program product, for example, a computer program tangibly embodied in a machine readable storage device (a computer-readable medium) to process the operations of a data processing device, for example, a programmable processor, a computer, or a plurality of computers or to control the operations. The computer programs such as the above-described computer program(s) may be recorded in any form of a programming language including compiled or interpreted languages, and may be executed as a standalone program or in any form included as another unit suitable to be used in a module, component, sub routine, or a computing environment. The computer program may be executed to be processed on a single computer or a plurality of computers at one site or to be distributed across a plurality of sites and then interconnected by a communication network.

The processors suitable to process a computer program include, for example, both general purpose and special purpose microprocessors, and any one or more processors of a digital computer of any kind. Generally, the processor may receive instructions and data from a read only memory, a random-access memory or both of a read only memory and a random-access memory. The elements of a computer may include at least one processor executing instructions and one or more memory devices storing instructions and data. In general, a computer may include one or more mass storage devices storing data, such as a magnetic disk, a magneto-optical disc, or an optical disc or may be coupled with them so as to receive data from them, to transmit data to them, or to exchange data with them. For example, information carriers suitable to embody computer program instructions and data include semiconductor memory devices, for example, magnetic Media such as hard disks, floppy disks, and magnetic tapes, optical Media such as compact disc read only memory (CD-ROM), and digital video disc (DVD), magneto-optical media such as floppy disks, ROM, random access memory (RAM), flash memory, erasable programmable ROM (EPROM), electrically erasable programmable ROM (EEPROM), and the like. The processor and the memory may be supplemented by a special purpose logic circuit or may be included by the special purpose logic circuit.

Furthermore, the computer-readable medium may be any available medium capable of being accessed by a computer and may include a computer storage medium.

Although the specification includes the details of a plurality of specific implementations, it should not be understood that they are restricted with respect to the scope of any invention or claimable matter. On the contrary, they should be understood as the description about features that may be specific to the specific example embodiment of a specific invention. Specific features that are described in this specification in the context of respective example embodiments may be implemented by being combined in a single example embodiment. On the other hand, the various features described in the context of the single example embodiment may also be implemented in a plurality of example embodiments, individually or in any suitable sub-combination. Furthermore, the features operate in a specific combination and may be described as being claimed. However, one or more features from the claimed combination may be excluded from the combination in some cases. The claimed combination may be changed to sub-combinations or the modifications of sub-combinations.

Likewise, the operations in the drawings are described in a specific order. However, it should not be understood that such operations need to be performed in the specific order or sequential order illustrated to obtain desirable results or that all illustrated operations need to be performed. In specific cases, multitasking and parallel processing may be advantageous. Moreover, the separation of the various device components of the above-described example embodiments should not be understood as requiring such the separation in all example embodiments, and it should be understood that the described program components and devices may generally be integrated together into a single software product or may be packaged into multiple software products.

In the meantime, example embodiments of the present invention disclosed in the specification and drawings are simply the presented specific example to help understand an example embodiment of the present invention and not intended to limit the scopes of example embodiments of the present invention. It is obvious to those skilled in the art that other modifications based on the technical idea of the present invention may be performed in addition to the example embodiments disclosed herein.

What is claimed is:

1. A silicon photonics-based electronic-photonic integrated circuit (EPIC), the EPIC comprising:
a silicon photonic integrated circuit (PIC) chip in which an optical device is mounted on a silicon-on-insulator (SOI) wafer comprising a trench region;
an electronic integrated circuit (EIC) chip mounted in the trench region of the PIC chip; and
an electrical interface configured to connect an electrode pad of the PIC chip and an electrode pad of the EIC chip.

2. The EPIC of claim 1, wherein the EIC chip is mounted on a silicon substrate of the SOI wafer in the trench region from which cladding oxide, silicon, and buried oxide (BOX) of the SOI wafer are removed.

3. The EPIC of claim 1, wherein the EIC chip is fixed to a silicon substrate of the SOI wafer using a thermally conductive adhesive.

4. The EPIC of claim 1, wherein a depth of the trench region is determined such that the electrode pad of the PIC chip and the electrode pad of the EIC chip have a same height.

5. The EPIC of claim 1, wherein the electrode pad of the PIC chip and the electrode pad of the EIC chip are designed to have a same pitch spacing.

6. A silicon photonics-based electronic-photonic integrated circuit (EPIC), the EPIC comprising:
a silicon photonic integrated circuit (PIC) chip in which an optical device is mounted on a silicon-on-insulator (SOI) wafer comprising a first trench region and a second trench region;
an electronic integrated circuit (EIC) chip mounted in the first trench region of the PIC chip;
an electrical interface configured to connect an electrode pad of the PIC chip and an electrode pad of the EIC chip; and
an N-channel fiber array block (FAB) having one or more channels mounted in the second trench region of the PIC chip.

7. The EPIC of claim 6, wherein the EIC chip is mounted on a silicon substrate of the SOI wafer in the first trench region from which cladding oxide, silicon, and buried oxide (BOX) of the SOI wafer are removed.

8. The EPIC of claim 6, wherein the N-channel FAB is mounted on a silicon substrate of the SOI wafer in the second trench region from which cladding oxide, silicon, and BOX of the SOI wafer are removed.

9. The EPIC of claim 6, wherein the EIC chip is fixed to a silicon substrate of the SOI wafer using a thermally conductive adhesive.

10. The EPIC of claim 6, wherein the N-channel FAB is fixed to a silicon substrate of the SOI wafer using an adhesive.

11. The EPIC of claim 6, wherein a depth of the first trench region is determined such that the electrode pad of the PIC chip and the electrode pad of the EIC chip have a same height.

12. The EPIC of claim 6, wherein the electrode pad of the PIC chip and the electrode pad of the EIC chip are designed to have a same pitch spacing.

13. A silicon photonics-based electronic-photonic integrated circuit (EPIC), the EPIC comprising:
a silicon photonic integrated circuit (PIC) chip in which an optical device is mounted on a silicon-on-insulator (SOI) wafer comprising a trench region;
an electronic integrated circuit (EIC) chip mounted in the trench region of the PIC chip;
an electrical interface configured to connect an electrode pad of the PIC chip and an electrode pad of the EIC chip; and
a printed circuit board (PCB) comprising a thermally conductive via disposed at a bottom of the PIC chip.

14. The EPIC of claim 13, wherein the PCB is fixed to an upper PCB on which an electrode pad is mounted using an adhesive.

15. The EPIC of claim 14, wherein a height of the upper PCB is determined such that the electrode pad of the upper PCB and the electrode pad of the EIC chip have a same height.

16. The EPIC of claim 13, wherein the EIC chip is mounted on a silicon substrate of the SOI wafer in the trench region from which cladding oxide, silicon, and buried oxide (BOX) of the SOI wafer are removed.

17. The EPIC of claim 13, wherein a depth of the trench region is determined such that the electrode pad of the PIC chip and the electrode pad of the EIC chip have a same height.
